(19) United States
(12) Patent Application Publication
(10) Pub. No.: US 2025/0351426 A1
(43) Pub. Date: Nov. 13, 2025

(54) SEMICONDUCTOR DEVICE

(71) Applicant: Samsung Electronics Co., Ltd., Suwon-si (KR)

(72) Inventors: Taiuk RIM, Suwon-si (KR); Sehyun KWON, Suwon-si (KR); Doyun KIM, Suwon-si (KR); Taeyoon AN, Suwon-si (KR); Jin-Seong LEE, Suwon-si (KR); Kyo-Suk CHAE, Suwon-si (KR)

(21) Appl. No.: 18/944,059

(22) Filed: Nov. 12, 2024

(30) Foreign Application Priority Data
May 9, 2024 (KR) 10-2024-0061428

(51) Int. Cl. H01L 29/78; H01L 29/423; H10B 12/00

(52) U.S. Cl. CPC H10D 30/637; H10B 12/315; H10D 64/513

(57) ABSTRACT

Provided is a semiconductor device, including a gate trench between a source region and a drain region on a substrate, a first gate insulating layer covering a lower surface and a sidewall of the gate trench, a second insulating layer in contact with an upper region of a sidewall of the first gate insulating layer in the gate trench, and a gate electrode in the gate trench, the gate electrode including a lower buried portion in contact with the first gate insulating layer, wherein the lower buried portion is in a lower region of the gate trench, and an upper buried portion is on the lower buried portion in an upper region of the gate trench, in which the lower buried portion includes a first conductive layer in contact with a sidewall surface and a lower region of the first gate insulating layer, the upper buried portion includes a work function adjustment layer on the second insulating layer, and a second conductive layer in the upper region of the gate trench, wherein the second conductive layer is in contact with the work function adjustment layer and the first conductive layer, and the second conductive layer includes a transition metal.

### CROSS-REFERENCE TO RELATED APPLICATION

This U.S. non-provisional application claims priority to Korean Patent Application No. 10-2024-0061428, filed in the Korean Intellectual Property Office on May 9, 2024, the entire contents of which are hereby incorporated by reference in their entirety.

### BACKGROUND

### Field

The present disclosure relates to a semiconductor device.

### Description of Related Art

A semiconductor device is a core component used to control or amplify an electrical signal in an electronic device, and various types of semiconductor devices may be manufactured. For example, a memory device may be mainly used to store and retrieve data, while a non-memory device may be used to control or amplify an electrical signal. In recent years, demand for the performance and functions of electronic devices is more intense than ever, essentially requiring high-performance characteristics of semiconductor devices, and the degree of integration of semiconductor devices is increasing to meet this requirement. Various methods for forming semiconductor devices with excellent performance and improved degree of integration are being studied.

In particular, a buried channel array transistor (BCAT) is applied to DRAM products, providing an improved degree of integration and also ensuring a sufficient effective distance. The BCAT includes a gate electrode filled in a trench formed between the source and drain regions of the substrate. Using this BCAT, the degree of integration of the integrated circuit device increases, resulting in the depth of the gate electrode filled in the trench formed between the source and drain regions being abnormally lowered, which may cause loss of the gate electrode and deteriorate the electrical characteristics.

### SUMMARY

The present disclosure provides a semiconductor device with improved electrical characteristics and reliability.

According to some aspects, a semiconductor device may include a gate trench between a source region and a drain region on a substrate, a first gate insulating layer covering a lower surface and a sidewall of the gate trench, a second insulating layer in contact with an upper region of a sidewall of the first gate insulating layer in the gate trench, and a gate electrode in the gate trench, wherein the gate electrode includes a lower buried portion in contact with the first gate insulating layer wherein the lower buried portion is in a lower region of the gate trench, and an upper buried portion on the lower buried portion in an upper region of the gate trench, in which the lower buried portion includes a first conductive layer in contact with sidewall and a lower region of the sidewall of the first gate insulating layer, the upper buried portion includes a work function adjustment layer on the second insulating layer, and a second conductive layer is in contact with the work function adjustment layer and the first conductive layer, and the second conductive layer includes a transition metal.

According to some aspects, a semiconductor device may include a source region and a drain region on a substrate and spaced apart from each other by a gate trench, a first gate insulating layer covering a lower surface and a sidewall of the gate trench, a second insulating layer in contact with an upper region of a sidewall of the first gate insulating layer in the gate trench, and a gate electrode including a lower buried portion surrounded by the first gate insulating layer and in a lower region of the gate trench, and an upper buried portion on the lower buried portion and in an upper region of the gate trench, in which the lower buried portion includes a first conductive layer surrounded by a sidewall and a lower region of the first gate insulating layer, the second insulating layer is on an upper surface of the first conductive layer and an upper region of the sidewall of the first gate insulating layer, the upper buried portion includes a work function adjustment layer surrounded by the second insulating layer, and a second conductive layer surrounded by the work function adjustment layer, and the second conductive layer includes a transition metal. According to some aspects, a memory device may include a semiconductor device, and a capacitor electrically connected to the semiconductor device. The memory device or semiconductor device may be a semiconductor chip. The semiconductor device may include a gate trench between a source region and a drain region on a substrate, a first gate insulating layer covering a lower surface and a sidewall of the gate trench, a second insulating layer in contact with an upper region of a sidewall of the first gate insulating layer in the gate trench, and a gate electrode including, in the gate trench, a lower buried portion in contact with the first gate insulating layer and wherein the lower buried portion is in a lower region of the gate trench, and an upper buried portion on the lower buried portion is in an upper region of the gate trench, in which the lower buried portion includes a first conductive layer in contact with a sidewall and a lower region of the first gate insulating layer, the upper buried portion includes a work function adjustment layer on the second insulating layer, and a second conductive layer is in contact with the work function adjustment layer and the first conductive layer, and the second conductive layer includes a transition metal.

In the semiconductor device according to some aspects of the present disclosure, leakage current can be reduced, and word line conductivity can be ensured.

According to some aspects of the present disclosure, the work function of the gate electrode can be reduced due to the work function adjustment layer in the upper region of the gate electrode of the semiconductor device, reducing the leakage current due to gate induced drain leakage (GIDL) phenomenon.

According to some aspects of the present disclosure, a portion of the conductive layer in the upper region of the gate electrode of the semiconductor device is buried in another conductive layer in the lower region of the gate electrode, so that the problem of word line resistance breakage due to the loss of the conductive layer can be improved even when the gate trench is formed at a low depth.

### BRIEF DESCRIPTION OF THE DRAWINGS

The above and other objects, features and advantages of the present disclosure will become more apparent to those of ordinary skill in the art by describing in detail example aspects thereof with reference to the accompanying drawings, in which:

FIG. 1 is a diagram illustrating an example of a semiconductor device;

FIG. 2 is a cross-sectional view taken along line A-A of FIG. 1;

FIG. 3 is a cross-sectional view of another example of a semiconductor device;

FIG. 4 is a cross-sectional view of another example of a semiconductor device;

FIG. 5 is a cross-sectional view of another example of a semiconductor device;

FIG. 6 is a cross-sectional view of another example of a semiconductor device;

FIG. 7 is a cross-sectional view of another example of a semiconductor device;

FIG. 8 is a diagram illustrating a configuration of an example of a memory device array;

FIG. 9 is a cross-sectional view taken along line B-B of FIG. 8; and

FIGS. 10 to 18 are cross-sectional views illustrating a process of manufacturing the semiconductor device illustrated in FIG. 2.

### DETAILED DESCRIPTION

In the following description, when a certain element is referred to as being “above” or “on” another element, it may refer to the certain element being not only directly above or on the certain element in contact, but also above the certain element contactlessly. Spatially relative terms, such as “above,” “upper,” “lower” and the like, may be used herein for ease of description to describe positional relationships, such as illustrated in the figures, for example. It will be understood that the spatially relative terms encompass different orientations of the device in addition to the orientation depicted in the figures. These spatially relative terms such as “above” and “below” as used herein have their ordinary broad meanings—for example element A can be above element B even if when looking down on the two elements there is no overlap between them (just as something in the sky is generally above something on the ground, even if it is not directly above).

Singular expressions include plural expressions as can be seen, for example, in the drawings. Thus, the description of a single item that is provided in plural should be understood to be applicable to the remaining plurality of items unless the context clearly dictates otherwise.

Throughout the specification, when a component is described as “includes” or “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

As used herein, the words “surround” and “surrounded” are intended to mean that an element is outside the other element. The elements may be touching or not. The surrounding element may or may not completely surround an inner element. The surrounding element does not need to completely surround the inner element, however. As used herein the term “covering” is intended to mean that an element is over or on or aside another element. The elements may be touching or not. Also an element on top need not cover an entire top surface of an element below to be considered “covering”. The term is intended to encompass one element covering all or any part of an element below it.

Unless the order of the steps of a method is clearly stated or stated to the contrary, the steps may be performed in any suitable order and are not necessarily limited to the order described.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

The connecting lines or connecting members between the components illustrated in the drawings are provided to illustrate functional connections and/or physical or circuit connections as an example, and may be replaced with or represented as additional various functional connections, physical connections, or circuit connections in an actual device.

A “semiconductor chip” may be a semiconductor device singulated from (e.g., cut from) a wafer.

All examples or illustrative terms used herein are provided only to describe the technical idea in detail and the aspects of the invention are not limited in scope by these examples or illustrative terms unless limited by the claims.

Hereinafter, a semiconductor device and a method of manufacturing the semiconductor device will be described in detail with reference to the accompanying drawings. In the drawings, the same reference numerals refer to the same or like components, and the size of each component in the drawings may be exaggerated for clarity and convenience of explanation. In addition, the aspects described herein are merely illustrative, and various modifications are possible from these aspects.

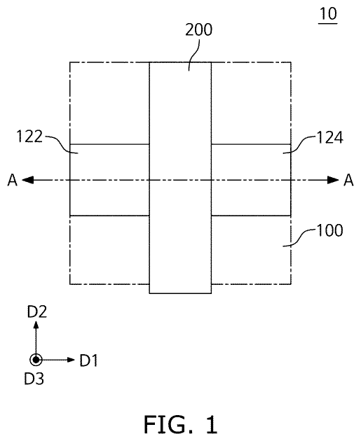

In the following description, in the illustrations in FIGS. 1 to 18, a first direction D1, a second direction D2, a fourth direction D4, and a fifth direction D5 represent the same plane, and a third direction D3 is perpendicular to the first direction, the second direction D2, the fourth direction D4, and the fifth direction D5. The first direction D1 and the second direction D2 are perpendicular to each other, and the fourth direction D4 and the fifth direction D5 are perpendicular to each other.

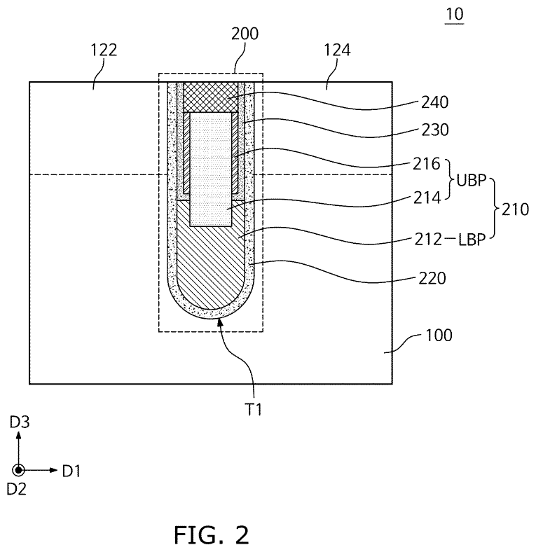

FIG. 1 is a diagram illustrating an example of a semiconductor device, and FIG. 2 is a cross-sectional view taken along line A-A of FIG. 1. The semiconductor device may be a memory device. For example, the memory device or semiconductor device may be a semiconductor chip. The semiconductor device may be a dynamic random access memory (DRAM), but is not limited thereto.

Referring to FIGS. 1 and 2, a semiconductor device 10 may include a source region 122 and a drain region 124 on a substrate 100 and spaced apart from each other, a gate trench T1 formed between the source region 122 and the drain region 124 on the substrate 100, a gate insulating layer 220 (also referred to herein interchangeably as a “first gate insulating layer”, to distinguish over the “second insulating layer” or “additional insulating layer”), covering a lower surface and a sidewall of the gate trench T1, a gate electrode 210 including, in the gate trench T1, a lower buried portion (LBP) in contact with the gate insulating layer 220 and filling a lower region of the gate trench T1, and an upper buried portion (UBP) on the lower buried portion (LBP) and filling an upper region of the gate trench T1, and a capping layer 240 on the gate electrode 210.

As used herein, the term “filling” is intended to mean that a component is within a space or region. The component may completely fill a space or region or partially fill the space or region within the scope of the term “filling”.

The substrate 100 may include a semiconductor substrate. The substrate 100 may include silicon, single crystal silicon, polysilicon, amorphous silicon, silicon germanium, single crystal silicon germanium, polycrystalline silicon germanium, carbon-doped silicon, or a combination thereof. The substrate 100 is a group III-V semiconductor substrate, for example, one of a binary compound, a ternary compound, or a quaternary compound formed by a combination of at least one of aluminum (Al), gallium (Ga), or indium (In) as a group III element and at least one of phosphorus (P), arsenic (As), or antimony (Sb) as a group V element.

The gate trench T1 formed by etching a partial region of the substrate 100 in the third direction D3 may be on the substrate 100. The source region 122 and the drain region 124 are spaced apart from each other in a horizontal direction (e.g., in the first direction D1) by the gate trench T1 on the substrate 100. The source region 122 and the drain region 124 may be opposite to each other in parallel in the horizontal direction (e.g., in first direction D1) with respect to the upper region of the gate trench T1. For example, the upper surface of the source region 122 and the drain region 124 and an upper surface of the substrate 100 may be coplanar to each other. In addition, lower surfaces of the source region 122 and the drain region 124 may be positioned higher than the lower surface of the gate trench T1. In addition, the source region 122 and the drain region 124 may be in contact with the sidewall of the gate trench T1.

The source region 122 and the drain region 124 may be formed by doping a partial region of the substrate 100 with an impurity. For example, the source region 122 and the drain region 124 may be formed by doping any one of phosphorus (P), arsenic (As), antimony (Sb), or boron (B) on a partial region of the substrate 100.

A gate 200 may be in the gate trench T1. The gate 200 may include the gate electrode 210, the gate insulating layer 220, an additional (or “second”) insulating layer 230, and the capping layer 240. The gate electrode 210 may partially fill the inside of the gate trench T1. The gate insulating layer 220 may be in contact with the lower surface and the sidewall of the gate trench T1. The gate electrode 210 may partially fill the inside of the gate trench T1, and the gate insulating layer 220 may be between the substrate 100 and the gate electrode 210 to surround the gate electrode 210. Accordingly, the gate electrode 210 may not be in direct contact with the lower surface and the sidewall of the gate trench T1. The second/additional insulating layer 230 may be in contact with an upper region of the sidewall of the gate insulating layer 220 in the gate trench T1. The capping layer 240 may be on the gate electrode 210. The second/additional insulating layer 230 may increase the thickness of a side insulating layer of the semiconductor device 10, thereby reducing the gate-induced drain leakage (GIDL) phenomenon.

The gate electrode 210 may include a lower buried portion (LBP) and an upper buried portion (UBP). The lower buried portion (LBP) may include a first conductive layer 212. The first conductive layer 212 may fill the lower region of the gate trench T1 and may be in contact with the lower surface of the gate insulating layer 220 and the lower region of the sidewall in the gate trench T1. In addition, because the lower buried portion (LBP) is in the lower region in the gate trench T1, it may not overlap, in the horizontal direction (e.g., the first and second directions D1 and D2), with the source region 122 and the drain region 124 which are parallel to the upper region of the gate trench T1.

The first conductive layer 212 may include a transition metal material. For example, the first conductive layer 212 may include at least one of molybdenum (Mo), ruthenium (Ru), rhodium (Rh), titanium (Ti), cobalt (Co), tantalum (Ta), or tungsten (W). However, aspects are not limited thereto, and the first conductive layer 212 may include not only at least one of molybdenum (Mo), ruthenium (Ru), rhodium (Rh), titanium (Ti), cobalt (Co), tantalum (Ta), or tungsten (W), but also other transition metal materials that can be deposited by atomic layer deposition (ALD) method. The first conductive layer 212 may include a compound including a transition metal material. For example, the first conductive layer 212 may include a transition metal nitride. In some aspects, the first conductive layer 212 may include at least one of titanium nitride (TiN) or tungsten nitride (WN), but is not limited thereto. In addition, the first conductive layer 212 may include a material or p-type material that has a mid-gap work function thermally stable at high temperatures (approximately 1000° C. or higher).

The upper buried portion UBP may include a work function adjustment layer 216 and a second conductive layer 214. The work function adjustment layer 216 may be in contact with the additional insulating layer 230 in the upper region of the sidewall of the gate insulating layer 220 in the gate trench T1. Accordingly, the work function adjustment layer 216 and the gate insulating layer 220 may not be in contact with each other. The second conductive layer 214 may be in contact with the first conductive layer 212 and the work function adjustment layer 216 while filling the upper region of the gate trench T1. For example, a lower portion of the second conductive layer 214 may be passed through an upper portion of the first conductive layer 212 and buried. Accordingly, the lower surface of the second conductive layer 214 may be positioned lower than an upper surface of the first conductive layer 212. In embodiments in which a portion of the second conductive layer 214 is buried in the first conductive layer 212, the problem of word line resistance breakage due to the loss of the first conductive layer 212 can be improved even when the gate trench T1 is formed at a low depth. In addition, the work function adjustment layer 216 may surround the second conductive layer 214, but may not cover the upper surface and lower surface of the second conductive layer 214. In addition, because the upper buried portion (UBP) is provided in the upper region in the gate trench T1, at least a portion of the upper buried portion (UBP) may overlap, in the horizontal direction (e.g., the first and second directions D1 and D2), with the source region 122 and the drain region 124 that are parallel to the upper region of the gate trench T1. Accordingly, at least a portion of the work function adjustment layer 216 and at least a portion of the second conductive layer 214 may overlap with the source region 122 and the drain region 124 in the horizontal directions (e.g., the first and second directions D1 and D2).

The second conductive layer 214 may include a transition metal. For example, the second conductive layer 214 may include at least one of molybdenum (Mo), ruthenium (Ru), rhodium (Rh), titanium (Ti), cobalt (Co), tantalum (Ta), or tungsten (W). However, aspects are not limited thereto, and the second conductive layer 214 may include not only at least one of molybdenum (Mo), ruthenium (Ru), rhodium (Rh), titanium (Ti), cobalt (Co), tantalum (Ta), or tungsten (W), but also other transition metal materials that can be deposited by atomic layer deposition (ALD) method. The second conductive layer 214 may include a compound including a transition metal material. For example, the second conductive layer 214 may include a transition metal nitride. In some aspects, the second conductive layer 214 may include at least one of titanium nitride (TiN) or tungsten nitride (WN), but is not limited thereto. In addition, the second conductive layer 214 may include a material or p-type material that has a mid-gap work thermally stable at high temperatures (for example, approximately 1000° C. or higher).

The second conductive layer 214 may include a transition metal that is the same as or different from the transition metal of the first conductive layer 212. In addition, the second conductive layer 214 may include a transition metal compound that is the same as or different from the transition metal compound of the first conductive layer 212. Alternatively, the second conductive layer 214 may include a material that is the same as or different from the material or p-type material with the mid-gap work function of the first conductive layer 212.

The work function adjustment layer 216 may include a material that has a lower work function than the first conductive layer 212 and the second conductive layer 214. For example, the work function adjustment layer 216 may include n-type doped polysilicon or metal (e.g., aluminum (Al)). In addition, the work function adjustment layer 216 may include a material having thermal stability at high temperatures (e.g., 1000° C. or higher) in subsequent processes. With the work function adjustment layer 216, the work function of the gate electrode 210 may be reduced. Accordingly, leakage current due to gate induced drain leakage (GIDL) phenomenon may be reduced. The capping layer 240 may be on the upper surfaces of the second conductive layer 214 and the work function adjustment layer 216.

At least a portion of the additional insulating layer 230 may be between a lower end of the work function adjustment layer 216 and at least a portion of the first conductive layer 212. For example, an end of the additional insulating layer 230 between the gate insulating layer 220 and the work function adjustment layer 216 may extend in the horizontal direction (e.g., the first and second directions D1 and D2). In this case, a portion of the additional insulating layer 230 interposed between the work function adjustment layer 216 and the first conductive layer 212 (e.g., a portion of the additional insulating layer 230 bent or protruding in the first direction D1) may be in contact with the second conductive layer 214. In this case, the portion of the additional insulating layer 230 interposed between the lower end of the work function adjustment layer 216 and the at least portion of the first conductive layer 212 may have a thickness of 10 Å or more. With the additional insulating layer 230 interposed between the lower end of the work function adjustment layer 216 and the at least portion of the first conductive layer 212, the GIDL phenomenon can be reduced.

The gate insulating layer 220 may include silicon oxide, silicon nitride, silicon oxynitride, high-k material, or a combination thereof. The high-k material may include a material having a dielectric constant greater than the dielectric constant of silicon oxide. For example, the high-k material may include a material having a dielectric constant greater than 3.9. In another example, the high-k material may include a material having a dielectric constant greater than 10. The high-k material may include at least one metallic element.

The high-k material may include a hafnium-including material. The hafnium-including material may include hafnium oxide, hafnium silicon oxide, hafnium silicon oxynitride, or a combination thereof. The high-k material may include lanthanum oxide, lanthanum aluminum oxide, zirconium oxide, zirconium silicon oxide, zirconium silicon oxynitride, aluminum oxide, and a combination thereof. Other known high-k materials may be used as the high-k material.

The additional insulating layer 230 may include silicon oxide, silicon nitride, silicon oxynitride, high-k material, or a combination thereof. For example, the additional insulating layer 230 may include the same material as the gate insulating layer 220.

The capping layer 240 may include an insulating material. For example, the capping layer 240 may include silicon nitride, silicon oxynitride, or a combination thereof. In addition, the capping layer 240 may include a combination of silicon nitride and silicon oxide. For example, after lining with silicon nitride, spin on dielectric (SOD) may be filled so as to form the capping layer 240. The capping layer 240 may be above the second conductive layer 214 and the work function adjustment layer 216. The additional insulating layer 230 may extend to a side surface of the capping layer 240 in the third direction D3. Accordingly, the side surface of the capping layer 240 may be surrounded by the additional insulating layer 230.

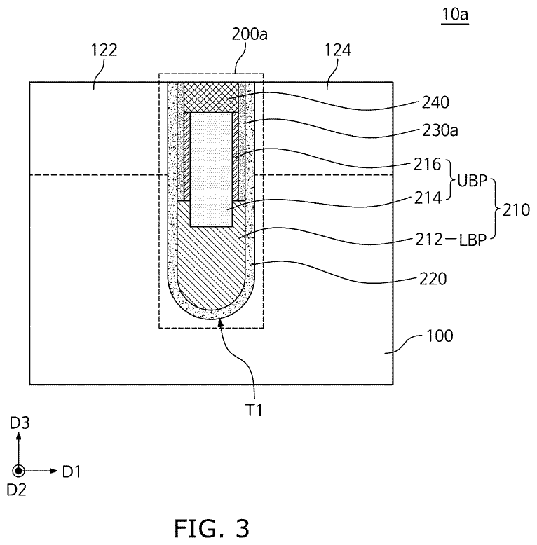

FIG. 3 is a cross-sectional view of another example of a semiconductor device.

The semiconductor device 10a of FIG. 3 may be substantially the same as the semiconductor device 10 of FIG. 2, but in this case, the at least portion of the additional insulating layer 230a is not between the lower end of the work function adjustment layer 216 and the first conductive layer 212. In describing FIG. 3, the elements or operations overlapping with FIGS. 1 and 2 are briefly described or not described, as it is understood that similar elements and operations have a similar description with respect to all of the Figures.

The additional insulating layer 230a may be in contact with the upper region of the sidewall of the gate insulating layer 220 in the gate trench T1. The second conductive layer 214 may partially fill the upper region in the gate trench T1, and the work function adjustment layer 216 may be between at least a portion of the second conductive layer 214 and at least a portion of the gate insulating layer 220 such that the side surface of the at least portion of the second conductive layer 214 may contact the work function adjustment layer 216. Accordingly, the second conductive layer 214 may not directly contact the gate insulating layer 220. In addition, at least a portion of the upper surface of the first conductive layer 212 may contact a lower surface of the additional insulating layer 230a and a lower surface of the work function adjustment layer 216. For example, the lower surface of the additional insulating layer 230a and the lower surface of the work function adjustment layer 216 in order on the gate insulating layer 220 may contact the at least portion of the upper surface of the first conductive layer 212.

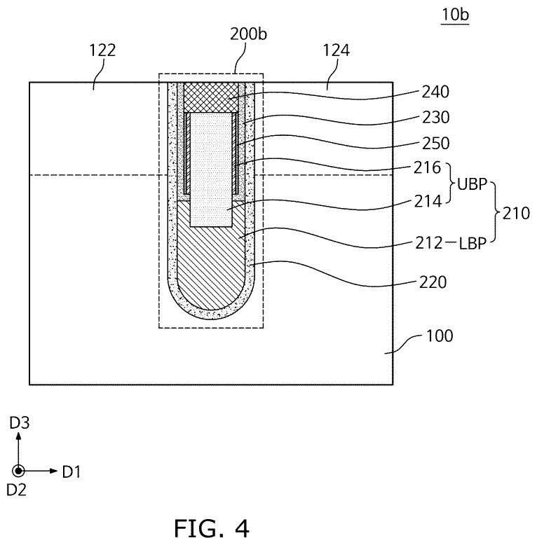

FIG. 4 is a cross-sectional view of another example of a semiconductor device.

The semiconductor device 10b of FIG. 4 may be substantially the same as the semiconductor device 10 of FIG. 2, except that it may further include a dipole layer 250. In describing FIG. 4, the elements or operations overlapping with FIGS. 1 and 2 are briefly described or not described.

Referring to FIG. 4, the semiconductor device 10b may further include the dipole layer 250 interposed between the work function adjustment layer 216 and the additional insulating layer 230. For example, the dipole layer 250 may be at a boundary between the work function adjustment layer 216 and the additional insulating layer 230, with one side surface of the dipole layer 250 being in contact with the work function adjustment layer 216, and the other side surface opposite the one side of the dipole layer 250 and the lower surface being in contact with the additional insulating layer 230.

The dipole layer 250 may include an oxide of a dipole element. For example, the dipole layer 250 may include at least one of zinc oxide, lanthanum aluminate, barium titanate, or lead zirconate titanate. However, the material forming the dipole layer 250 is not limited to the above, and may include a compound of a dipole element having a low work function. The dipole layer 250 may reduce the effective work function between the upper buried portion UBP and the source region 122 and/or between the upper buried portion UBP and the drain region 124.

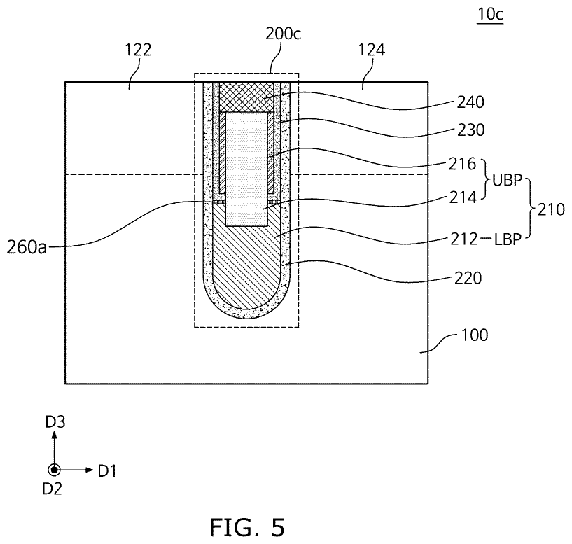

FIGS. 5 to 7 are cross-sectional views of another example of a semiconductor device.

The semiconductor devices 10c, 10d, and 10e of FIGS. 5 to 7 may be substantially the same as the semiconductor device 10 of FIG. 2, except that they may further include barrier layers 260a, 260b, and 260c. In describing FIGS. 5 to 7, the elements or operations overlapping with FIGS. 1 and 2 are briefly described or not described.

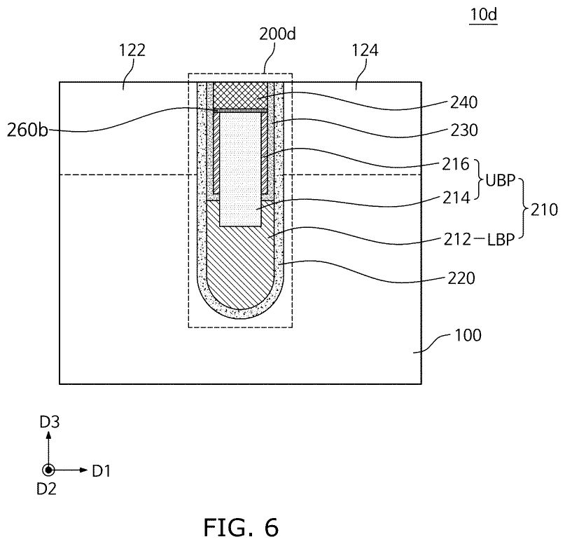

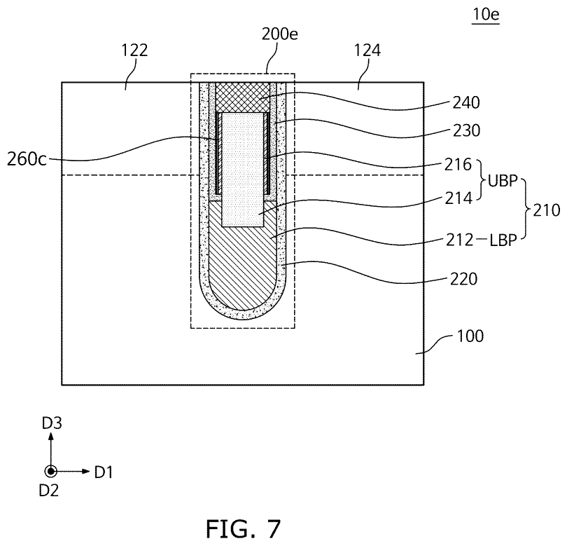

Referring to FIG. 5, the semiconductor device 10c may further include a barrier layer 260a between the first conductive layer 212 and the additional insulating layer 230. Alternatively or additionally, referring to FIG. 6, the semiconductor device 10d may further include a barrier layer 260b above the work function adjustment layer 216 and the second conductive layer 214. Alternatively or additionally, referring to FIG. 7, the semiconductor device 10e may further include a barrier layer 260c between the additional insulating layer 230 and the work function adjustment layer 216. The barrier layers 260a, 260b, and 260c may serve to block impurities diffused from the low-resistance material or to prevent mutual diffusion and reaction between different materials.

The barrier layers 260a, 260b, and 260c may include a nitride or a metal. For example, the barrier layers 260a, 260b, and 260c may include at least one of titanium nitride (TIN), tungsten nitride (WN), aluminum nitride (AlN), or silicon nitride (SiN). Alternatively, the barrier layers 260a, 260b, and 260c may include at least one of titanium (Ti) or tantalum (Ta).

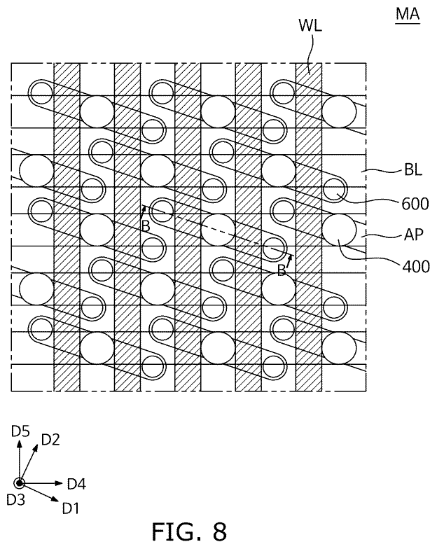

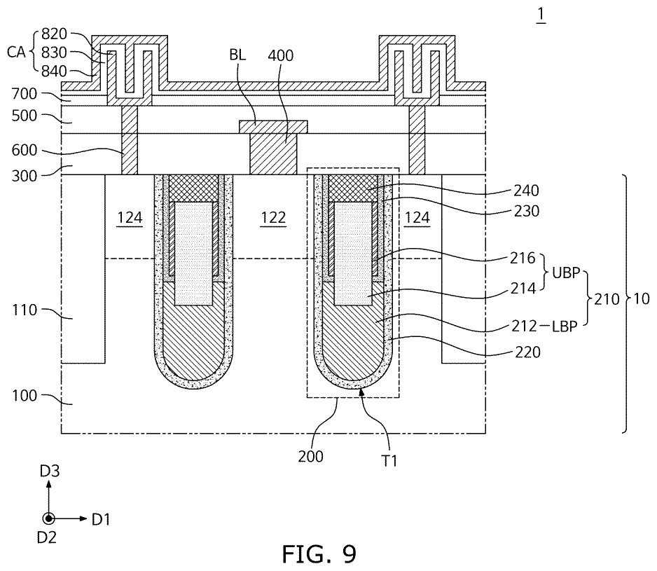

FIG. 8 is a diagram illustrating a configuration of an example of a memory device array. In addition, FIG. 9 is a cross-sectional view taken along line B-B of FIG. 8. The memory device may be a dynamic random access memory (DRAM), but is not limited thereto.

The memory device array MA may include a plurality of active patterns AP. Each of a plurality of active patterns AP may have a shape of a bar extending in the first direction D1. Each of the plurality of active patterns AP may have an isolated shape. The plurality of active patterns AP may be defined by a device isolation film 110 on the substrate 100. The device isolation film 110 may be a shallow trench isolation (STI) region formed by trench etching. The device isolation film 110 may include silicon oxide, silicon nitride, or a combination thereof. A source region (e.g., the source region 122 of FIG. 2) and a drain region (e.g., the drain region 124 of FIG. 2) may be in each active pattern AP, adjacent to the gate electrode 210.

The memory device array MA may include a plurality of word lines WL. Each of the plurality of word lines WL may represent a gate electrode (the gate electrode 210 of FIG. 2). Each of the plurality of word lines WL may be to intersect at least a portion of the plurality of active patterns AP. Each of the plurality of word lines WL may extend in the fifth direction D5 and may be spaced apart from each other in the fourth direction D4. Each of the plurality of word lines WL may be in trenches formed in the substrate 100. For example, as illustrated in FIG. 9, the gate electrode 210 may be in the gate trench T1 formed in the substrate 100.

The memory device array MA may include a plurality of bit lines BL. Each of a plurality of bit lines BL may be electrically connected to a source region (e.g., the source region 122 of FIG. 2) of the memory device through a first contact 400. Each of the plurality of bit lines BL may intersect at least a portion of the plurality of active patterns AP. Each of the plurality of bit lines BL may extend in the fourth direction D4 and may be spaced apart from each other in the fifth direction D5.

A plurality of memory device arrays MA may include a plurality of capacitors CA. Each of the plurality of capacitors may be electrically connected to a drain region (e.g., the drain region 124) of the memory device through a second contact 600.

FIG. 9 illustrates an example of a memory device 1 forming the memory device array MA of FIG. 8.

Referring to FIG. 9, the memory device 1 may include the semiconductor device 10, a bit line BL, and a capacitor CA. FIG. 9 illustrates that the memory device 1 includes the semiconductor device 10 illustrated in FIG. 2, but the memory device 1 may include any one of the semiconductor devices 10a, 10b, 10c, 10d, and 10e illustrated in FIGS. 3 to 7. In addition, FIG. 9 illustrates a semiconductor device including one source region 122 and two drain regions 124, with a capacitor CA being connected to each of the drain regions 124, but this is only for illustration purposes, and aspects are not limited thereto.

The memory device 1 may further include, on the substrate 100 of the semiconductor device 10, interlayer insulating films 300 and 500 covering the source region 122, the drain region 124, and the gate 200.

The first interlayer insulating film 300 may be on the substrate 100 and the device isolation film 110. The first interlayer insulating film 300 may include a silicon oxide film, a silicon nitride film, or a silicon oxynitride film.

The bit line BL may be on the first interlayer insulating film 300. The bit line BL may include various kinds of conductive materials. For example, the bit line BL may include at least one of polycrystalline silicon, titanium nitride (TiN), tungsten (W), titanium (Ti), ruthenium (Ru), or tungsten nitride (WN).

A first through hole may be in a partial region of the first interlayer insulating film 300. The memory device 1 may further include the first contact 400 filled in the first through hole. For example, the first through hole may be formed to expose the source region 122, and the first contact 400 may be in contact with the source region 122. The bit line BL may be on the first interlayer insulating film 300 to be in contact with the first contact 400. Accordingly, the bit line BL may be electrically connected to the source region 122 through the first contact 400. The shape and configuration of the first contact 400 may be variously changed, and the first contact 400 may include various kinds of conductive materials.

The second interlayer insulating film 500 may be on the first interlayer insulating film 300 and the bit line BL. The second interlayer insulating film 500 may include a silicon oxide film, a silicon nitride film, or a silicon oxynitride film. The second interlayer insulating film 500 may be formed to bury the bit line BL.

A second through hole may be formed in a partial region of the second interlayer insulating film 500. The memory device 1 may further include the second contact 600 filled in the second through hole. The second through hole may extend to the lower surface of the first interlayer insulating film 300. For example, the second through hole may be formed to expose the drain region 124, and the second contact 600 may be in contact with the drain region 124. The capacitor CA may be on the second interlayer insulating layer 500 to be in contact with the second contact 600. Accordingly, the capacitor CA may be electrically connected to the drain region 124 through the second contact 600. The shape and configuration of the second contact 600 may be variously changed, and the second contact 600 may include various kinds of conductive materials.

The capacitor CA may be on the second interlayer insulating film 500. The capacitor CA may include a first electrode 820, a second electrode 840, and a dielectric layer 830 interposed between the first electrode 820 and the second electrode 840. The first electrode 820 may have a cylindrical shape with a lower portion blocked. The second electrode 840 may cover the first electrode 820.

The first electrode 820 and the second electrode 840 may include various kinds of conductive materials. The first electrode 820 and the second electrode 840 may include at least one of polycrystalline silicon, titanium nitride (TiN), tungsten (W), titanium (Ti), ruthenium (Ru), or tungsten nitride (WN). The dielectric layer 830 may include various kinds of insulating materials. For example, the dielectric layer 830 may include at least one high dielectric constant material, such as zirconium oxide (ZrO₂), aluminum oxide (Al₂O₃), or hafnium oxide (Hf₂O₃).

A support layer 700 may be between the second electrode 840 and the second interlayer insulating film 500. The support layer 700 may be on an outer sidewall of the first electrode 820 to prevent the first electrode 820 from falling. The support layer 700 may include an insulating material.

In the semiconductor device 10, the second conductive layer 214 of the upper buried portion (UBP) and the first conductive layer 212 of the lower buried portion (LBP) forming the word line (WL) extend in the third direction D3, so that the problem of word line resistance breakage due to the loss of the first conductive layer 212 can be improved even when the gate trench T1 is formed at a low depth. In addition, the work function of the gate electrode 210 can be reduced due to the work function adjustment layer 216 between the second conductive layer 214 and the additional insulating layer 230. Accordingly, the leakage current to the source and drain regions 122 and 124 caused by the GIDL phenomenon generated from the word line WL can be reduced. Accordingly, electrical characteristics of the semiconductor device 10 can be improved.

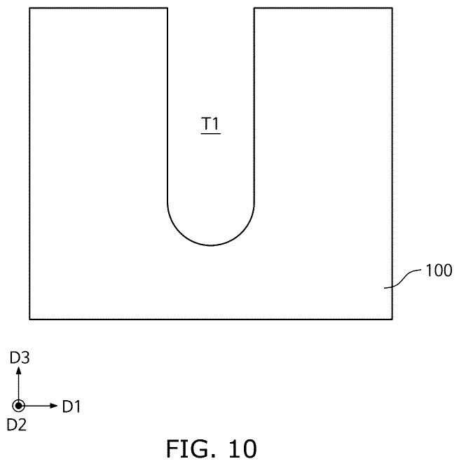

FIGS. 10 to 18 are cross-sectional views illustrating a process of manufacturing the semiconductor device illustrated in FIG. 2.

Referring to FIG. 10, a portion of the substrate 100 may be patterned to form the gate trench T1.

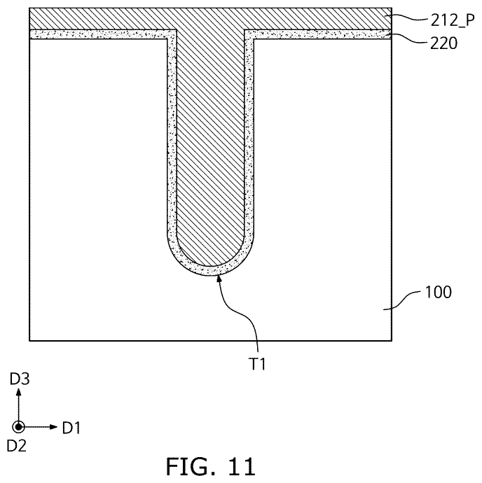

Referring to FIG. 11, the gate insulating layer 220 covering a lower surface and a sidewall of the gate trench T1 may be on the substrate 100. The gate insulating layer 220 may be formed by a thermal oxidation process. In other aspects, the gate insulating layer 220 may be formed by chemical vapor deposition (CVD) or atomic layer deposition (ALD). If the gate insulating layer 220 includes a silicon oxide film, the gate insulating layer 220 may have a thickness of 35 Å or more. A preliminary first conductive layer 212_P filling the gate trench T1 may be on the gate insulating layer 220.

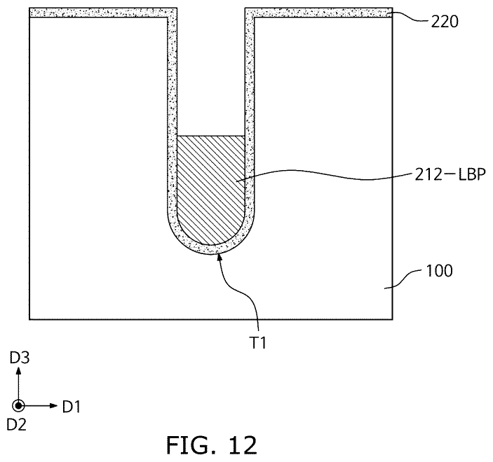

Referring to FIG. 12, the preliminary first conductive layer 212_P may be patterned to form a lower buried portion (LBP) which is in contact with a lower region of the sidewall of the gate insulating layer 220 in the gate trench T1. The lower buried portion (LBP) may include the first conductive layer 212 filling the lower region of the gate trench T1 and contacting the lower surface of the gate insulating layer 220 and the lower region of the sidewall.

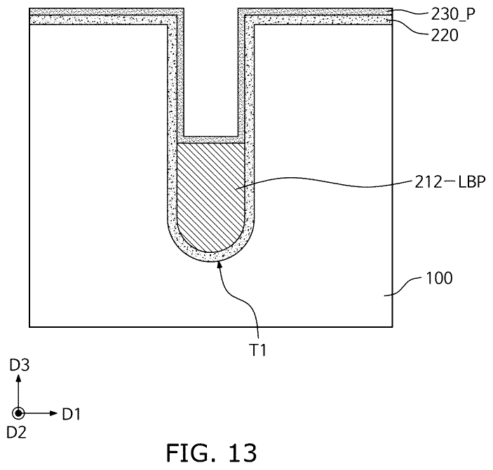

Referring to FIG. 13, a preliminary additional insulating layer 230_P covering a portion of the upper surface of the first conductive layer 212 and the gate insulating layer 220 may be formed. The preliminary additional insulating layer 230_P may have a thickness of 10 Å or more. In another aspect, before forming the preliminary additional insulating layer 230_P, a barrier layer (e.g., the barrier layer 260a of FIG. 5) may be formed on the upper surface of the first conductive layer 212.

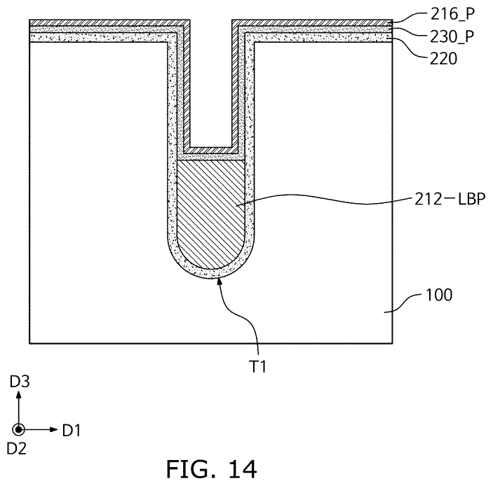

Referring to FIG. 14, a preliminary work function adjustment layer 216_P covering the preliminary additional insulating layer 230_P may be formed. The preliminary work function adjustment layer 216_P may be formed using an atomic layer deposition method ALD.

In another aspect, before forming the preliminary work function adjustment layer 216_P, a barrier layer (e.g., the barrier layer 260c of FIG. 7) may be formed on the preliminary additional insulating layer 230_P. In another aspect, before forming the preliminary work function adjustment layer 216_P, a dipole layer (e.g., the dipole layer 250 of FIG. 4) may be formed on the preliminary additional insulating layer 230_P.

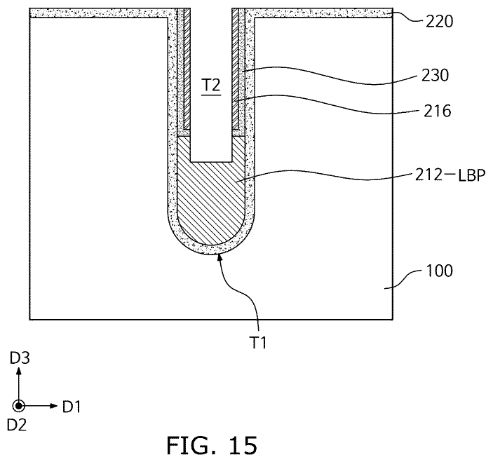

Referring to FIG. 15, the preliminary additional insulating layer 230_P and the preliminary work function adjustment layer 216_P may be patterned to form the additional insulating layer 230, which is in contact with the upper region of the sidewall of the gate insulating layer 220, and the work function adjustment layer 216 which is on the additional insulating layer 230. In this process, part of the upper portion of the first conductive layer 212 may also be patterned. Accordingly, an upper trench T2 exposing a portion of the first conductive layer 212 may be formed.

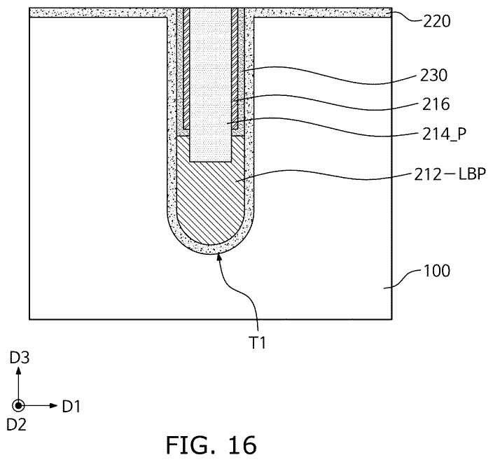

Referring to FIG. 16, a preliminary second conductive layer 214_P filling the upper trench T2 may be formed on the part of the upper portion of the first conductive layer 212 and the work function adjustment layer 216.

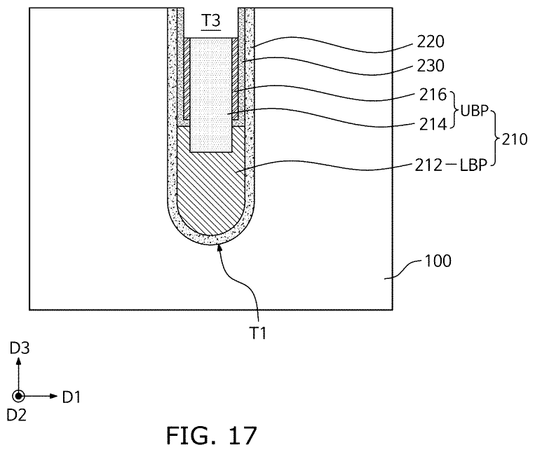

Referring to FIG. 17, the preliminary second conductive layer 214_P and the work function adjustment layer 216 may be patterned to form an upper buried portion UBP filling the upper region of the gate trench T1. The upper buried portion UBP may include the work function adjustment layer 216 on the additional insulating layer 230, and the second conductive layer 214 partially filling the upper trench T2 and contacting the part of the upper portion of the first conductive layer 212 and the work function adjustment layer 216. The lower portion of the second conductive layer 214 may be passed through the upper portion of the first conductive layer 212 to be buried. For example, the lower surface of the second conductive layer 214 may be positioned lower than the upper surface of the first conductive layer 212. In this process, a capping layer trench T3 exposing a portion of the additional insulating layer 230 may be formed.

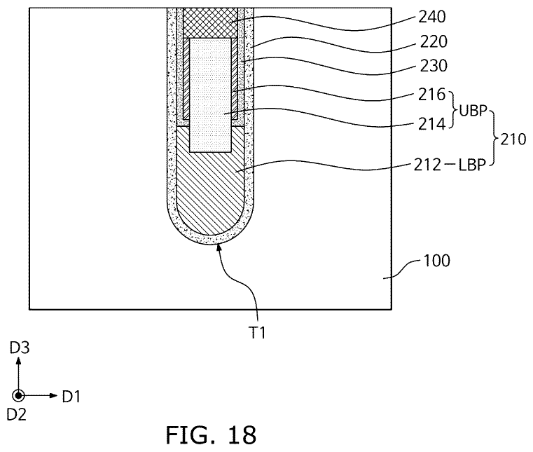

Referring to FIG. 18, the capping layer 240 filling the capping layer trench T3 may be formed. In another aspect, before forming the capping layer 240, a barrier layer (e.g., the barrier layer 260b of FIG. 6) may be formed on the upper surfaces of the second conductive layer 214 and the work function adjustment layer 216.

Accordingly, according to aspects according to the technical idea of the present invention, a semiconductor device with a reduced leakage current and improved word line conductivity can be provided.

Although the present invention has been described herein by way of certain aspects and drawings, the present invention is not limited thereto, and various changes and modifications can be made within the equivalent scope of the technical idea of the present invention and the claims by those of ordinary skill in the art.

What is claimed is:

1. A semiconductor device comprising:
a source region and a drain region on a substrate, wherein the source region and drain region are spaced apart from each other;
a gate trench between the source region and the drain region on the substrate;
a first gate insulating layer covering a lower surface and a sidewall of the gate trench;
a second insulating layer in contact with an upper region of a sidewall of the first gate insulating layer in the gate trench; and
a gate electrode in the gate trench, wherein the gate electrode includes a lower buried portion in contact with the first gate insulating layer, wherein the lower buried portion is in a lower region of the gate trench, and an upper buried portion is on the lower buried portion in an upper region of the gate trench,
wherein
the lower buried portion includes a first conductive layer in contact with a sidewall and a lower region of the first gate insulating layer,
the upper buried portion includes a work function adjustment layer on the second insulating layer, and a second conductive layer in the upper region of the gate trench, wherein the second conductive layer is in contact with the work function adjustment layer and the first conductive layer, and
the second conductive layer includes a transition metal.

2. The semiconductor device according to claim 1, wherein a lower portion of the second conductive layer is buried in an upper portion of the first conductive layer.

3. The semiconductor device according to claim 1, wherein the first conductive layer includes the same transition metal as the transition metal of the second conductive layer.

4. The semiconductor device according to claim 3, wherein the transition metal includes at least one transition metal selected from the group consisting of molybdenum (Mo), ruthenium (Ru), rhodium (Rh), titanium (Ti), cobalt (Co), tantalum (Ta), and tungsten (W).

5. The semiconductor device according to claim 1, wherein the work function adjustment layer includes a material having a work function lower than a work function of the first conductive layer and lower than a work function of the second conductive layer.

6. The semiconductor device according to claim 5, wherein the work function adjustment layer includes an n-type doped polysilicon or a metal.

7. The semiconductor device according to claim 1, wherein the second insulating layer includes at least one material selected from the group consisting of silicon oxide, silicon nitride, silicon oxynitride, and a high-k material.

8. The semiconductor device according to claim 1, wherein at least a portion of the second insulating layer is between a lower end of the work function adjustment layer and the first conductive layer.

9. The semiconductor device according to claim 8, wherein a thickness of the portion of the second insulating layer between the lower end of the work function adjustment layer and the first conductive layer is 10 Å or more.

10. The semiconductor device according to claim 1, further comprising a dipole layer between the work function adjustment layer and the second insulating layer.

11. The semiconductor device according to claim 10, wherein the dipole layer includes at least one material selected from the group consisting of zinc oxide, lanthanum aluminate, barium titanate, and lead zirconate titanate.

12. The semiconductor device according to claim 1, further comprising a barrier layer
between the first conductive layer and the second insulating layer,
between the second insulating layer and the work function adjustment layer, or
above the work function adjustment layer and the second conductive layer.

13. The semiconductor device according to claim 12, wherein the barrier layer includes at least one material selected from the group consisting of titanium nitride (TiN), tungsten nitride (WN), aluminum nitride (AlN), silicon nitride (SiN), titanium, and tantalum.

14. A semiconductor device, comprising:
a source region and a drain region on a substrate, wherein the source region and the drain region are spaced apart from each other by a gate trench;
a first gate insulating layer covering a lower surface and a sidewall of the gate trench;
a second insulating layer in contact with an upper region of a sidewall of the first gate insulating layer in the gate trench; and
a gate electrode including a lower buried portion surrounded by the first gate insulating layer and in a lower region of the gate trench, and an upper buried portion on the lower buried portion and in an upper region of the gate trench,
wherein
the lower buried portion includes a first conductive layer surrounded by a sidewall and a lower region of the first gate insulating layer,
the second insulating layer is on an upper surface of the first conductive layer and on an upper region of the sidewall of the first gate insulating layer,
the upper buried portion includes a work function adjustment layer surrounded by the second insulating layer, and a second conductive layer surrounded by the work function adjustment layer, and
the second conductive layer includes a transition metal.

15. The semiconductor device according to claim 14, wherein a lower portion of the second conductive layer is buried in an upper portion of the first conductive layer.

16. The semiconductor device according to claim 14, wherein the first conductive layer includes the same transition metal as the transition metal of the second conductive layer.

17. The semiconductor device according to claim 15, wherein the transition metal includes at least one transition metal selected from the group consisting of molybdenum (Mo), ruthenium (Ru), rhodium (Rh), titanium (Ti), cobalt (Co), tantalum (Ta), and tungsten (W).

18. The semiconductor device according to claim 14, wherein the work function adjustment layer includes a material having a work function lower than a work function of the first conductive layer, and the work function adjustment layer includes a material having a work function lower than a work function of the second conductive layer.

19. The semiconductor device according to claim 18, wherein the work function adjustment layer includes an n-type doped polysilicon or a metal.

20. A memory device, comprising:
a semiconductor device; and
a capacitor electrically connected to the semiconductor device,
wherein the semiconductor device includes:
a source region and a drain region on a substrate and spaced apart from each other;
a gate trench between the source region and the drain region on the substrate;
a first gate insulating layer covering a lower surface and a sidewall of the gate trench;
a second insulating layer in contact with an upper region of a sidewall of the first gate insulating layer in the gate trench; and
a gate electrode including, in the gate trench, wherein the gate electrode includes a lower buried portion in contact with the first gate insulating layer, wherein the lower buried portion is in a lower region of the gate trench, and an upper buried portion on the lower buried portion in an upper region of the gate trench,
wherein
the lower buried portion includes a first conductive layer in contact with a sidewall and a lower region of the first gate insulating layer,
the upper buried portion includes a work function adjustment layer on the second insulating layer, and a second conductive layer in the upper region of the gate trench, wherein the second conductive layer is in contact with the work function adjustment layer and the first conductive layer, and
the second conductive layer includes a transition metal.
